(19) United States
(12) Patent Application Publication
(10) Pub. No.: US 2025/0155883 A1
(43) Pub. Date: May 15, 2025

(54) PROCESS MODELING PLATFORM FOR SUBSTRATE MANUFACTURING SYSTEMS

(71) Applicant: Applied Materials, Inc., Santa Clara, CA (US)

(72) Inventors: Prashanth Kothnur, San Jose, CA (US); Ala Moradian, San Jose, CA (US); Umesh Madhav Kelkar, Cupertino, CA (US); Phillip Stout, Santa Clara, CA (US); Badri Ramamurthi, Los Gatos, CA (US); Karthik Ramanathan, Bangalore (IN); Ananth Bhoj, Round Rock, TX (US); Dalong Zhao, San Jose, CA (US)

(21) Appl. No.: 18/939,065

(22) Filed: Nov. 6, 2024

(30) Foreign Application Priority Data
Nov. 9, 2023 (IN) 202341076555

(51) Int. Cl. G05B 19/418

(52) U.S. Cl. CPC G05B 19/41885; G05B 2219/42058; G05B 2219/45031

(57) ABSTRACT

In one aspect of the present disclosure, a method includes obtaining, by a processing device, input data indicative of a first set of process parameters. The method further includes providing the input data to a first process model. The method further includes obtaining, from the first process model, first predictive output indicative of performance of a first process operation in accordance with the first set of process parameters. The method further includes providing the first predictive output to a second process model. The method further includes obtaining, from the second process model, second predictive output indicative of performance of a second process operation, different than the first process operation or a repetition of the first process operation, in accordance with the first set of process parameters. The method further includes performing a corrective action in view of the second predictive output.

### RELATED APPLICATIONS

This application claims the benefit of Indian application Ser. No. 202341076555, filed Nov. 9, 2023, entitled “PROCESS MODELING PLATFORM FOR SUBSTRATE MANUFACTURING SYSTEMS,” which is incorporated by reference herein.

TECHNICAL FIELD

The present disclosure relates to methods associated with models used for assessment of manufactured devices, such as semiconductor devices. More particularly, the present disclosure relates to a process modeling platform for substrate manufacturing systems.

### BACKGROUND

Products may be produced by performing one or more manufacturing processes using manufacturing equipment. For example, semiconductor manufacturing equipment may be used to produce substrates via semiconductor manufacturing processes. Products are to be produced with particular properties, suited for a target application. Various models such as digital twin models are used in various process control and predictive functions associated with manufacturing equipment. Models associated with manufacturing equipment are trained and/or calibrated using data associated with the manufacturing equipment.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular embodiments of the disclosure or any scope of the claims. Its sole purpose is to present some concepts of the disclosure in a simplified form as a prelude to the more detailed description that is presented later.

In one aspect of the present disclosure, a method includes obtaining, by a processing device, input data indicative of a first set of process parameters. The method further includes providing the input data to a first process model. The method further includes obtaining, from the first process model, first predictive output indicative of performance of a first process operation in accordance with the first set of process parameters. The method further includes providing the first predictive output to a second process model. The method further includes obtaining, from the second process model, second predictive output indicative of performance of a second process operation, different than the first process operation, in accordance with the first set of process parameters. The method further includes performing a corrective action in view of the second predictive output.

In another aspect of the present disclosure, a method includes obtaining, by a processing device, first data indicative of performance of a first process operation by a substrate processing system. The method further includes providing the first data to a first process model associated with a second process operation of the substrate processing system. The second process operation may be different than the first process operation or may be a repetition of the first process operation. The method further includes obtaining output of the first process model including predictive results of performance of the second process operation. The method further includes performing a corrective action in view of the output of the first process model.

In another aspect of the present disclosure, a method includes obtaining, by a processing device, a first indication of a target feature of a substrate. The method further includes providing the first indication to a process modeling module, wherein the process modeling module comprises a first process model and a second process model. The method further includes receiving as output from the process modeling module a set of process inputs associated with the target feature. The method further includes performing a corrective action in view of the set of process inputs.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system architecture, according to some embodiments.

FIG. 2 depicts a block diagram of an example data set generator, according to some embodiments.

FIG. 3 is a block diagram illustrating a system for generating output data, according to some embodiments.

FIG. 4A is a flow diagram of a method for generating a data set for a model, according to some embodiments.

FIG. 4B is a flow diagram of a method for utilizing a process modeling platform for determining predictive data associated with a multi-operation substrate processing procedure, according to some embodiments.

FIG. 4C is a block diagram of a method for utilizing a process modeling platform for adjusting performance of one or more process operations, according to some embodiments.

FIG. 4D is a flow diagram of a method for utilizing a process modeling platform for generating a substrate including target features, according to some embodiments.

FIG. 5 is a view of a GUI 500A for user interaction with a process modeling platform, according to some embodiments.

FIG. 6 is a block diagram illustrating a computer system, according to some embodiments.

### DETAILED DESCRIPTION

Described herein are technologies related to a platform for generating and providing information indicative of process chamber performance to improve manufacturing of substrates. Manufacturing equipment is used to produce products, such as substrates (e.g., wafers, semiconductors). Manufacturing equipment may include a manufacturing or processing chamber to separate the substrate from the environment. The properties of produced substrates are to meet target values to facilitate specific functionalities. Manufacturing parameters are selected to produce substrates that meet the target property values. Many manufacturing parameters (e.g., hardware parameters, process parameters, etc.) contribute to the properties of processed substrates. Manufacturing systems may control parameters by specifying a set point for a property value and receiving data from sensors disposed within the manufacturing chamber, and making adjustments to the manufacturing equipment until the sensor readings match the set point. Data generated by physical process chambers (e.g., sensor data, virtual sensor data, virtual metrology data, etc.) and data generated by corresponding virtual process chambers may be utilized in generating input/output mappings, in designing new process recipes, in updating current process recipes, and the like. Physics-based models, statistical models, and trained machine learning models may be utilized to improve performance of manufacturing equipment.

Models are utilized to provide an understanding of processing operations. A quality of performance of a process operation may be understood based on output of one or more models. Quality of performance may refer to the degree to which a process operation meets design goals, such as threshold property conditions of a processed substrate, threshold process conditions in the chamber, or the like. Models may include physics-based models, such as physics-based digital twin models. Models may include data-based models, such as machine learning models. Models may include statistical models, heuristic models, rule-based models, combinations of models or types of models, etc.

Models may be used to predict one or more properties of a substrate process operation. Properties may include chamber conditions, substrate conditions, hardware conditions, etc. Models indicative of chamber performance quality may be based on physical chamber conditions or virtual chamber conditions. Models based on physical chamber conditions may be provided, as input, data associated with performance of one or more process operations. For example, manufacturing parameters, substrate design parameters, and/or sensor data may be provided to one or more models. The one or more models may generate virtual sensor data, predicted substrate metrology data, or other types of data indicative of process operation performance quality. Models based on physical chamber conditions may be physics-based models. Models based on physical chamber conditions may be calibrated physics-based models. Models based on physical chamber conditions may be digital twin models. Models based on physical chamber conditions may be machine learning models, data-based models, physics-based models, rule-based models, heuristic models, statistical models, hybrid models (e.g., that use a combination of physics-based models and machine learning models trained on data to better predict an output), etc. One example of a hybrid model that may be used is a physics informed neural network (PINN) model. Models based on physical chamber conditions may receive data based on physical performance of substrate processing operations, which may be expensive to generate in terms of processing materials, disposal of processed substrates, energy, environmental impact, etc.

Models based on virtual chamber conditions may be provided, as input, one or more virtual processing input conditions. Virtual processing input conditions may or may not correspond to physical processing input conditions (e.g., manufacturing or hardware parameters). Models based on virtual chamber conditions may be data-based models. Models based on virtual chamber conditions may be machine learning models. Models based on virtual chamber conditions may be artificial intelligence-based models. Models based on virtual chamber conditions may be physics-based models, heuristic models, statistical models, rule-based models, etc. Input conditions may be provided to a model and virtual substrate processing performed. Output from one or more models may be provided, indicative of predicted operation performance quality associated with the given input conditions. Models based on virtual chamber conditions may be less costly to run, but establishing models, particularly data-based models, may involve providing a large amount of training and/or calibration data, labeling the data, ensuring that virtual chamber performance and physical chamber performance remain consistent, etc.

In a substrate manufacturing process, a substrate may undergo many processing operations. The processing operations may include diverse processing conditions. The processing operations may include diverse process goals. The processing operations may include operations performed in different process chambers. The processing operations may include different processes, e.g., different physical, chemical, electrical, or other mechanisms. The processing operations may be represented by different models, e.g., different physics-based models, different data-based models, different rule-based or heuristic models, etc. The substrate may undergo many process operations, represented by many different models and/or modeling techniques, sequentially to generate a finished substrate. The substrate may undergo several process operations (e.g., different types of processes) in several different process chambers. For example, a substrate may undergo an etch process in a chamber configured to perform etch operations, then be moved to a chamber configured to perform deposition processes to undergo a deposition process, etc. A completed substrate may undergo hundreds of process recipes involving many different processing equipment.

In some systems, various types of models are accessed, utilized, and/or understood separately. For example, models for different process operations may be utilized separately. Output from one model representing a first process operation for a substrate may be provided as input to a second model representing a second process operation for the substrate. Cascading effects across a number of process operations (represented by a number of process models) may be difficult to identify or quantify in such systems.

As a further example, models for assessing process chamber quality and/or processing operation performance quality may be separated into modeling based on sensor data of processing operations performed on physical process chambers, and modeling based on processing operations performed by virtual process chambers, such as digital twins corresponding to physical process chambers. Modeling based on physical process operations may be used in assessing chamber performance, predicting substrate metrology, etc. Modeling based on virtual process operations may be used in predicting results of a process recipe under development, predicting process conditions and/or substrate properties, etc. Such categories of models may be of different construction (e.g., physics-based vs. data-based models). Such categories may be of differing usefulness to different users. Models may be accessed via different platforms or applications in some systems. For a user interested in quality of a chamber, multiple models may be of use, which may be difficult or inconvenient to access via various model platforms.

In some systems, various models may exist for a particular process chamber, process chamber type, process operation, or the like. For example, one or more models may be utilized to predict or assess substrate properties, one or more models may be utilized to predict temperatures of the process chamber or substrate, models may be utilized to predict magnetic field properties, models may be utilized to predict plasma properties, etc. Such models may be accessed via different computing devices, different platforms, different applications, or the like. Such separation of models may cause inconvenience or difficulty in building an understanding of process chamber quality.

In some systems, models associated with various process chambers may be further separated. For example, a tool may include a number of process chambers configured to perform different types of process operations, such as deposition operations, etch operations, anneal operations, lithography operations, doping operations, etc. The tool may include chambers for performing physical vapor deposition (PVD) operations, chemical vapor deposition (CVD) operations, atomic layer deposition (ALD) operations, etch operations, lithography operations, etc. To view performance data associated with a process tool including more than one chamber, models associated with individual chambers and/or individual chamber types may be accessed via different platforms, applications, or the like. Such separation of models may cause inconvenience or difficulty in displaying data indicative of performance quality of a process tool.

In some systems, a single process chamber or type of process chamber may be capable of providing manufacturing conditions associated with a range of process operations. For example, multiple types of operations may be performed in a single chamber, which may each be associated with one or more separate models. In some embodiments, substrate processing models may be chamber agnostic, e.g., a model may not be associated with a particular process chamber, particular process chamber type, or the like.

In some systems, models associated with various tools or manufacturing facilities may be further separated. In a similar manner to separation of models associated with various chambers, accessing, by a user, models or model data associated with different tools or different facilities may be inconvenient, difficult, and/or expensive in terms of time, training, expertise, etc. Such separation of models may cause inconvenience or difficulty in displaying data indicative of performance quality of a manufacturing facility or set of facilities.

Methods and systems of the present disclosure may address one or more shortcomings of conventional solutions. A comprehensive manufacturing equipment performance quality application, program, platform, or the like may be constructed. The comprehensive platform may provide, to a user, access to many models associated with performance of manufacturing equipment. The comprehensive platform may provide access to models predicting various properties associated with the manufacturing equipment. The comprehensive platform may provide access to models associated with various tools, processing operations, chambers, facilities, etc. The comprehensive platform may provide access to models that generate predictions based on physical processing operations of the manufacturing equipment. The comprehensive platform may provide access to models that generate predictions based on virtual process operations of the manufacturing equipment. The comprehensive platform may provide various data displays for displaying process operation data, process operation performance quality data, etc. The comprehensive platform may be utilized in improving or creating process recipes. The comprehensive platform may be utilized in developing process recipes. The comprehensive platform may be utilized in identifying manufacturing faults. The comprehensive platform may be utilized in determining root causes of manufacturing faults. The comprehensive platform may be utilized in identifying drifting and/or aging of manufacturing equipment. The comprehensive platform may be utilized in identifying failure of one or more components of manufacturing equipment. The comprehensive platform may be utilized in recommending maintenance for manufacturing equipment. The comprehensive platform may be utilized in recommending replacement of one or more components of manufacturing equipment. The comprehensive platform may be utilized in optimization of process recipes or operations, e.g., based on target process outcomes, product properties, or the like.

The comprehensive platform may provide capability of modeling for multiple process operations of a substrate processing procedure. For example, the comprehensive platform may provide capability of modeling a sequence of process operations, which may be performed in a sequence of process chambers, may include looped or cyclic processes, may include many types of process operations (e.g., deposition, etch, doping, annealing, lithography, nitridation, etc.), or the like.

The comprehensive platform may enable selection of one or more target process chambers. Selection of the target process chamber may include selection of a manufacturing facility, selection of a tool including the target process chamber, selection of a type or category of chamber, selection of a type of process operation associated with the chamber, selection of a substrate type associated with the chamber, or the like.

The comprehensive process modeling platform may include a user interface, such as a graphical user interface (GUI). A user interface may be utilized in selecting modeling inputs for the process modeling platform. A user may provide input for use in substrate process modeling. In some embodiments, one or more inputs to a process modeling platform may be provided by a substrate manufacturing system, such as sensor data indicative of conditions of a process chamber, metrology data indicative of performance of a substrate, etc. Modeling capabilities may be performed responsive to user selection, responsive to manufacturing operations, etc. In some embodiments, input to the comprehensive process modeling platform may include simulation inputs corresponding to process inputs, e.g., process recipe operations, substrate processing conditions, manufacturing system parameters, etc. Output from the comprehensive process modeling platform may include predictive data associated with substrate performance (e.g., one or more substrate features of interest) based on the simulation inputs. In some embodiments, input to the comprehensive process modeling platform may include target substrate output, e.g., one or more target substrate features, characteristics, or the like. Output from the comprehensive process modeling platform may include predictive process inputs, e.g., process conditions (e.g., of a series of process operations, which may be of multiple types, and/or input substrate properties) predicted to generate a substrate meeting target substrate output specifications. In some embodiments, input to the comprehensive process modeling platform may include a target process result optimization, target process result weighting, or the like. For example, input to the process modeling platform may include an indication that a target characteristic of the process is to be optimized, such as reduction in process time, maximizing throughput, minimizing material used, minimizing cost of operations, minimizing energy use, minimizing environmental impact, or the like. Input to the process modeling platform may include an indication of weight of importance of various process result factors. Output from the process modeling platform may include indications of process conditions, recipe operations, or the like that satisfy the input target process result optimizations. In some embodiments, input to the comprehensive process modeling platform may include data indicative of a manufacturing process, e.g., manufacturing system sensor data, substrate metrology data, etc. Output from the comprehensive process modeling platform may include one or more updates to operations of the manufacturing process (e.g., adjustment to recipes of future process operations for improved substrate outcomes), updates to one or more models of the platform (e.g., to account for drift, aging, or changing conditions of the manufacturing equipment), or the like. Output from the comprehensive process modeling platform may include predictions of categorization of products produced using input process conditions. For example, presence or absence of a void in a gapfill application (e.g., material deposition filling a trench or hole) may be predicted and output by the comprehensive modeling platform.

In some embodiments, user selection of a chamber, a category of models, target data, or the like results in display of one or more sets of data via a GUI. Further division into categories may be performed by the comprehensive platform. For example, a monitor data mode may be divided into virtual sensor data (e.g., sensor data provided from physics-based and/or digital twin models based on chamber sensor data) and measured sensor data (e.g., data from chamber sensors, metrology tools, or the like). An explore data mode may be divided into a predictor mode (e.g., input to one or more models includes process/simulation knobs, output includes indications of quality of performance) and an explorer mode (e.g., input to one or more models includes target output of a process, output includes the process knob inputs that are predicted to result in the target output). Various data presentations, including histograms, time traces, substrate property maps, or other data presentation methods may be provided via the GUI.

Systems and methods of the present disclosure provide advantages over conventional methods. By providing a process modeling platform for models associated with manufacturing equipment quality, cost of operations to improve processing quality may be decreased, in terms of user time, training for user expertise, confidence and accuracy of adjustments made to the manufacturing equipment, etc. For example, a process modeling platform may be configured to determine cascading effects through a number of process operations, including various types of processes, which may occur in multiple process chambers. The process modeling platform may utilize output of one model for input to another model, repeatedly, to determine correlations between initial inputs and final predicted outputs. Further, including multiple modeling frameworks in a single comprehensive platform enables cross checking to monitor for chamber degradation, model degradation, component failure, required maintenance, chamber aging, and the like. Including access to many models of different construction, design, intent, type, category, etc., in a single comprehensive platform enables a more thorough understanding of chamber performance, which may improve outcomes associated with chamber maintenance, chamber and recipe design, substrate design, substrate manufacturing, etc.

In one aspect of the present disclosure, a method includes obtaining, by a processing device, input data indicative of a first set of process parameters. The method further includes providing the input data to a first process model. The method further includes obtaining, from the first process model, first predictive output indicative of performance of a first process operation in accordance with the first set of process parameters. The method further includes providing the first predictive output to a second process model. The method further includes obtaining, from the second process model, second predictive output indicative of performance of a second process operation, different than the first process operation, in accordance with the first set of process parameters. The method further includes performing a corrective action in view of the second predictive output.

In another aspect of the present disclosure, a method includes obtaining, by a processing device, first data indicative of performance of a first process operation by a substrate processing system. The method further includes providing the first data to a first process model associated with a second process operation of the substrate processing system. The second process operation is different than the first process operation. The method further includes obtaining output of the first process model including predictive results of performance of the second process operation. The method further includes performing a corrective action in view of the output of the first process model.

In another aspect of the present disclosure, a method includes obtaining, by a processing device, a first indication of a target feature of a substrate. The method further includes providing the first indication to a process modeling module, wherein the process modeling module comprises a first process model and a second process model. The method further includes receiving as output from the process modeling module a set of process inputs associated with the target feature. The method further includes performing a corrective action in view of the set of process inputs.

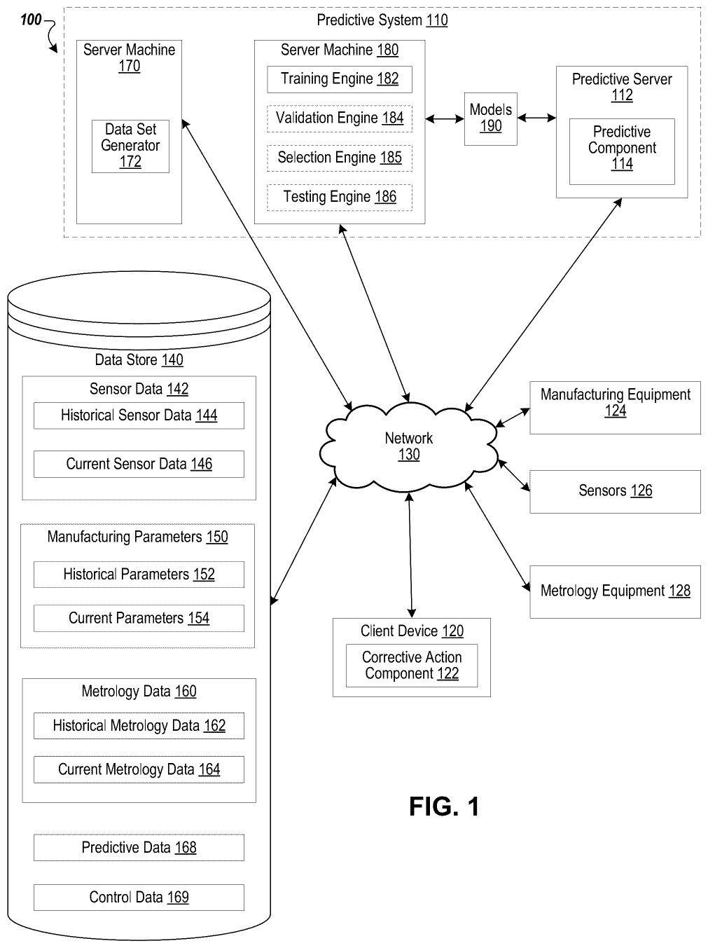

FIG. 1 is a block diagram illustrating an exemplary system 100 (exemplary system architecture), according to some embodiments. The system 100 includes a client device 120, manufacturing equipment 124, sensors 126, metrology equipment 128, model hosting server 112 (e.g., that hosts models such as digital twins), and data store 140. The model hosting server 112 may be part of predictive system 110. Predictive system 110 may further include server machines 170 and 180.

Sensors 126 may provide sensor data 142 associated with manufacturing equipment 124 (e.g., associated with producing, by manufacturing equipment 124, corresponding products, such as substrates). Sensor data 142 may be used to ascertain equipment health and/or product health (e.g., product quality). Manufacturing equipment 124 may produce products following a recipe or performing runs over a period of time. In some embodiments, sensor data 142 may include values of one or more of optical sensor data, spectral data, temperature (e.g., heater temperature), spacing (SP), pressure, High Frequency Radio Frequency (HFRF), radio frequency (RF) match voltage, RF match current, RF match capacitor position, voltage of Electrostatic Chuck (ESC), actuator position, electrical current, flow, power, voltage, etc. Sensor data 142 may include historical sensor data 144 and current sensor data 146. Current sensor data 146 may be associated with a product currently being processed, a product recently processed, a number of recently processed products, etc. Current sensor data 146 may be used as input to a model, e.g., to generate predictive data 168, control data 169, etc. Historical sensor data 144 may include data stored associated with previously produced products. Historical sensor data 144 may be used to train and/or calibrate a model, e.g., model 190. Historical sensor data 144 and/or current sensor data 146 may include attribute data, e.g., labels of manufacturing equipment ID or design, sensor ID, type, and/or location, label of a state of manufacturing equipment, such as a present fault, service lifetime, etc. In some embodiments, current sensor data 146 may be provided to a process modeling platform, e.g., for adjusting performance of subsequent process operations based on performance of previously performed process operations.

Sensor data 142 may be associated with, correlated to, or indicative of manufacturing parameters such as hardware parameters (e.g., hardware settings or indications of installed components, e.g., size, make, model, type, etc.) of manufacturing equipment 124 or process parameters (e.g., heater settings, gas flow, etc.) of manufacturing equipment 124. Data associated with some hardware parameters and/or process parameters may, instead or additionally, be stored as manufacturing parameters 150, which may include historical manufacturing parameters 152 (e.g., associated with historical processing runs) and current manufacturing parameters 154. Manufacturing parameters 150 may be indicative of input settings to the manufacturing device (e.g., heater power, gas flow, etc.). Sensor data 142 and/or manufacturing parameters 150 may be provided while the manufacturing equipment 124 is performing manufacturing processes (e.g., equipment readings while processing products). Sensor data 142 may be different for each product (e.g., each substrate). Substrates may have property values (film thickness, film strain, etc.) measured by metrology equipment 128. Metrology equipment 128 may include equipment included in a process tool or chamber, metrology equipment integrated with a tool, metrology equipment in a standalone facility, etc. Metrology data 160 may be a component of data store 140. Metrology data 160 may include historical metrology data 162 (e.g., metrology data associated with previously processed products). Metrology data 160 may include current metrology data 164 (e.g., metrology data associated with measurements taken during substrate processing, between substrate processing operations, metrology data from recently produced substrates, or the like). In some embodiments, metrology data 160 may be utilized for screening substrates for additional processing, for updating or adjusting subsequent process operations based on results of previous process operations, updating of process recipes and/or manufacturing parameters, or the like. Current metrology data 164 may be provided to a process modeling platform, e.g., for performing modeling of multiple process operations, process operation types, operations of multiple process chambers, or the like for generating control data 169. Historical metrology data 162 may be utilized for training one or more models (e.g., model 190).

In some embodiments, metrology data 160 may be provided without use of a standalone metrology facility, e.g., in-situ metrology data (e.g., metrology or a proxy for metrology collected during processing), integrated metrology data (e.g., metrology or a proxy for metrology collected while a product is within a chamber or under vacuum, but not during processing operations), inline metrology data (e.g., data collected after a substrate is removed from vacuum), etc. Metrology data 160 may include current metrology data (e.g., metrology data associated with a product currently or recently processed).

In some embodiments, sensor data 142, metrology data 160, or manufacturing parameters 150 may be processed (e.g., by the client device 120 and/or by the model hosting server 112). Processing of the sensor data 142 may include generating features. In some embodiments, the features are a pattern in the sensor data 142, metrology data 160, and/or manufacturing parameters 150 (e.g., slope, width, height, peak, etc.). In some embodiments, the features are a combination of values from the sensor data 142, metrology data 160, and/or manufacturing parameters 150 (e.g., power derived from voltage and current, etc.). Sensor data 142 may include features and the features may be used by predictive component 114 for performing signal processing and/or for obtaining predictive data 168. Predictive data 168 (e.g., including virtual sensor data 167, virtual substrate data 169, or other types of predictive data) may be used for performance of a corrective action. Predictive data 168 may be presented to a user, e.g., via a graphical user interface, via client device 120, or the like.

Each instance (e.g., set) of sensor data 142 may correspond to a product (e.g., a substrate), a set of manufacturing equipment, a type of substrate produced by manufacturing equipment, or the like. Each instance of metrology data 160 and manufacturing parameters 150 may likewise correspond to a product, a set of manufacturing equipment, a type of substrate produced by manufacturing equipment, or the like. The data store may further store information associating sets of different data types, e.g., information indicative that a set of sensor data, a set of metrology data, and a set of manufacturing parameters are all associated with the same product, manufacturing equipment, type of substrate, etc.

In some embodiments, predictive system 110 may generate predictive data 168 using supervised machine learning. Supervised machine learning may include utilizing a machine learning model that was trained using labeled data. Labeled data may include sensor data labeled with metrology data, sensor data labeled with probe data to generate virtual sensor data, manufacturing parameters labeled with sensor data or metrology data, etc. Labeled data may include any training input data of interest in connection with outcome data. Physics-based models may be calibrated in a similar way, by using some labeled data to correct or adjust one or more parameters of a physics-based model. In some embodiments, predictive system 110 may generate predictive data 168 using unsupervised machine learning. For example, predictive data 168 includes output from a machine learning model that was trained using unlabeled data, output may include clustering results, principle component analysis, anomaly detection, etc. In some embodiments, predictive system 110 may generate predictive data 168 using semi-supervised learning. For example, training data may include a mix of labeled and unlabeled data, etc.

In some embodiments, predictive system 110 generates control data 169. Control data 169 may include adjustments to one or more substrate processing operations based on performance of previous process operations. For example, current sensor data 146 indicative of conditions of a process chamber during processing of a substrate may be provided to a process modeling platform. The process modeling platform may utilize a sequence of process models representing a number of process operations that are to be performed on the substrate subsequent to the operation associated with the provided sensor data. The process modeling platform may recommend one or more adjustments to a process recipe for improving performance of the substrate processing operations as control data 169. The adjustments may be based on adjusting parameters to reduce a difference between measured sensor data and target sensor data. The adjustments may be based on adjusting parameters to reduce a difference between predicted performance of the substrate after a sequence of process operations (e.g., based on output of a modeling platform including modeling capability of multiple process operations, multiple process chambers, multiple types of process operations, loops of process operations, or the like) and target performance of the substrate. Performance may include predicted usage of the substrate, one or more features or characteristics of the substrate, optical, chemical, or electrical properties of the substrate, defect count, type, or density of the substrate, or any other substrate performance metric of instance that may be modeling by the process modeling platform.

Client device 120, manufacturing equipment 124, sensors 126, metrology equipment 128, model hosting server 112, data store 140, server machine 170, and server machine 180 may be coupled to each other via network 130 for generating predictive data 168 and/or control data 169 to perform corrective actions. In some embodiments, network 130 may provide access to cloud-based services. Operations performed by client device 120, predictive system 110, data store 140 etc., may be performed by virtual cloud-based devices.

In some embodiments, network 130 is a public network that provides client device 120 with access to the model hosting server 112, data store 140, and other publicly available computing devices. In some embodiments, network 130 is a private network that provides client device 120 access to manufacturing equipment 124, sensors 126, metrology equipment 128, data store 140, and other privately available computing devices. Network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

Client device 120 may include computing devices such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc. Client device 120 may include a corrective action component 122. Corrective action component 122 may receive user input (e.g., via a Graphical User Interface (GUI) displayed via the client device 120) of an indication associated with manufacturing equipment 124. Client device 120 may include one or more displays, one or more augmented reality (AR) devices (e.g., AR headsets), one or more virtual reality devices (e.g., VR headsets), and/or other devices for user interaction. In some embodiments, corrective action component 122 transmits the indication to the predictive system 110, receives output (e.g., predictive data 168) from the predictive system 110, determines a corrective action based on the output, and causes the corrective action to be implemented. In some embodiments, corrective action component 122 obtains sensor data 142 (e.g., current sensor data) associated with manufacturing equipment 124 (e.g., from data store 140, etc.) and provides sensor data 142 (e.g., current sensor data 146) associated with the manufacturing equipment 124 to predictive system 110.

In some embodiments, corrective action component 122 receives an indication of a corrective action from the predictive system 110 and causes the corrective action to be implemented. Each client device 120 may include an operating system that allows users to one or more of generate, view, or edit data (e.g., indication associated with manufacturing equipment 124, corrective actions associated with manufacturing equipment 124, etc.). Client device 120 may execute an application (e.g., a process modeling platform) including a graphical user interface (GUI) to display data to a user and/or receive input from a user.

Client device 120 may cause one or more models (e.g., models 190) to be executed. Client device 120 may cause one or more machine learning models to be executed. Client device 120 may cause one or more physics-based models to be executed. Client device 120 may cause one or more statistical, rule-based, heuristic, or other types of models to be executed. Client device 120 may execute a process modeling platform for providing access to one or more models to a user. Client device 120 may execute a process modeling platform for generating predictions associated with a sequence of process operations, including different types of operations, and influences of various operational parameters on substrate performance.

In some embodiments, metrology data 160 (e.g., historical metrology data 162) corresponds to historical property data of products (e.g., products processed using manufacturing parameters associated with historical sensor data 144 and historical manufacturing parameters 152 of manufacturing parameters 150) and predictive data 168 is associated with predicted property data (e.g., of products to be produced or that have been produced in conditions recorded by current sensor data 146 and/or current manufacturing parameters 154). In some embodiments, predictive data 168 is or includes predicted metrology data (e.g., virtual metrology data) of the products to be produced or that have been produced according to conditions recorded as current sensor data 146, current measurement data, current metrology data and/or current manufacturing parameters. In some embodiments, predictive data 168 is or includes an indication of any abnormalities (e.g., abnormal products, abnormal components, abnormal manufacturing equipment 124, abnormal energy usage, etc.) and optionally one or more causes of the abnormalities. In some embodiments, predictive data 168 is an indication of change over time or drift in some component of manufacturing equipment 124, sensors 126, metrology equipment 128, and the like. In some embodiments, predictive data 168 is an indication of an end of life of a component of manufacturing equipment 124, sensors 126, metrology equipment 128, or the like. In some embodiments, predictive data 168 is an indication of progress of a processing operation being performed, e.g., to be used for process control.

In some embodiments, a process modeling platform may be utilized for generating, viewing, manipulating, etc., data associated with one or more process chambers. The process modeling platform may be used to execute a number of models, including models of different types, construction, function, category, etc. The comprehensive modeling platform may execute one or more models for generating virtual substrate data as predictive data 168. Virtual substrate data may include data generated by one or more models executing virtual substrate processing operations. For example, virtual substrate data may be data generated in association with a digital twin model of a process chamber, multiple digital twin models associated with multiple process chambers, multiple process models that are chamber agnostic, a virtual process procedure including a number of different process operations, etc. As used herein, a digital twin model is a virtual model of a physical object (e.g., process chamber). It may span the object's lifecycle and uses real-time data sent from sensors on the object to simulate the behavior and monitor operations of the object. A digital twin of a process chamber may be configured to perform in a way that emulates the physical process chamber, when the physical and digital process chambers are provided corresponding inputs (e.g., process inputs corresponding to simulation inputs). A digital twin model may be or include a physics-based model, a data-based (e.g., machine learning) model, a hybrid model (including features of both data-based and physics-based models), etc.

A process modeling platform may enable execution of a large number of models associated with a substrate processing chamber. Analysis of performance of a substrate processing procedure (e.g., recipe) may include monitoring of performance of physical process operations performed in one or more physical chambers. Analysis of chamber performance may include executing virtual process operations in a virtual process chamber (e.g., digital twin). Analysis of chamber performance may include monitoring of performance of virtual process operations. Analysis of physical processing operations may enable performance of corrective actions, e.g., by indicating recommended recipe updates, recommended maintenance, failing and/or aging chamber components, etc. Performance and analysis of virtual processing operations may provide similar benefits, in addition to providing means to test substrate processing operations (e.g., during process recipe development) without costs associated with physical substrate processing, such as materials, energy, chamber time, disposal of resulting substrates, environmental impact, etc. Further, comparison of physical and virtual chamber performance may provide indications of chamber component aging or failing, recommended maintenance, recommended corrective actions, etc.

Design and optimization of substrate processing procedures (e.g., process recipes) may be costly in terms of time, test substrates, test materials, subject matter expertise, etc. Additionally, a sequence of operations for manufacturing a substrate may include a large number of operations, which may include many different types of operations (e.g., etch, deposition, nitridation, annealing, lithography, masking, and other types of operations). Modeling a complex multi-operation recipe may be difficult. Generating an understanding of which simulation and/or process inputs, providing at which point of a multi-operation procedure, correlate to on-substrate outputs, may be an expensive, slow, tedious, or impossible task for complex substrate processing procedures. Providing a process modeling platform enables correspondences between simulation inputs (e.g., correlated to process inputs such as manufacturing parameters, process recipe, etc.) and performance outputs (e.g., substrate features) to be traced through a number of process operations, process operation types, process chambers, process chamber types, process models describing physical processes, process models directed toward predicting different conditions or performance features, etc. A process modeling platform may enable process recipe design, e.g., by enabling adjustment of simulation knobs at one or more stages of processing to be reflected in outputs at later stages (e.g., later operations) of processing. A process modeling platform may enable process recipe design, e.g., by enabling input of one or more target outcomes (e.g., substrate features, target optimization targets such as cost, throughput, or environmental impact, etc.), and performance of modeling operations across a number of process models to generate simulation inputs that achieve the one or more target outcomes. Performing such analysis in a conventional system (e.g., by providing output from one model as input to another model outside a platform that enables tracing of impacts through the various models) may be difficult, costly, time-intensive, or impossible.

Performing manufacturing processes that result in defective products can be costly in time, energy, products, components, manufacturing equipment 124, the cost of identifying the defects and discarding the defective product, etc. By inputting sensor data 142 (e.g., manufacturing parameters that are being used or are to be used to manufacture a product) into predictive system 110, receiving output of predictive data 168, and performing a corrective action based on the predictive data 168, system 100 can have the technical advantage of avoiding the cost of producing, identifying, and discarding defective products.

Performing manufacturing processes that result in failure of the components of the manufacturing equipment 124 can be costly in downtime, damage to products, damage to equipment, express ordering replacement components, etc. By inputting sensor data 142 (e.g., indicative of manufacturing parameters that are being used or are to be used to manufacture a product), manufacturing parameters 150, metrology data 160, measurement data, etc., to a model 190, receiving output of predictive data 168, and performing corrective action (e.g., predicted operational maintenance, such as replacement, processing, cleaning, etc. of components) based on the predictive data 168, system 100 can have the technical advantage of avoiding the cost of one or more of unexpected component failure, unscheduled downtime, productivity loss, unexpected equipment failure, product scrap, or the like. Monitoring the performance over time of components, e.g. manufacturing equipment 124, sensors 126, metrology equipment 128, virtual and physical process chambers, and the like, may provide indications of degrading components.

Manufacturing parameters may be suboptimal for producing product which may have costly results of increased resource (e.g., energy, coolant, gases, etc.) consumption, increased amount of time to produce the products, increased component failure, increased amounts of defective products, increased cost of producing products, increased energy expenditure, increased environmental impact, etc. By inputting input data indicative of manufacturing processes to a model 190 (e.g., current sensor data 146 indicative of conditions of a substrate processing operation, current metrology data 164 indicative of performance of one or more substrate processing operations on a substrate, etc.), receiving output from the model, and performing (e.g., based on model-generated predictive data 168) a corrective action of updating manufacturing parameters (e.g., setting optimal manufacturing parameters), system 100 can have the technical advantage of using optimal manufacturing parameters (e.g., hardware parameters, process parameters, optimal design) to avoid costly results of suboptimal manufacturing parameters.

Corrective actions may be associated with one or more of Computational Process Control (CPC), Statistical Process Control (SPC) (e.g., SPC on electronic components to determine process in control, SPC to predict useful lifespan of components, SPC to compare to a graph of 3-sigma, etc.), Advanced Process Control (APC), model-based process control, preventative operative maintenance, design optimization, updating of manufacturing parameters, updating manufacturing recipes, feedback control, machine learning modification, or the like.

In some embodiments, the corrective action includes providing an alert (e.g., an alarm to stop or not perform the manufacturing process if the predictive data 168 indicates a predicted abnormality, such as an abnormality of the product, a component, or manufacturing equipment 124). In some embodiments, a machine learning model is trained to monitor the progress of a processing run (e.g., monitor in-situ sensor data to predict if a manufacturing process has reached completion). In some embodiments, the machine learning model may send instructions to end a processing run when the model determines that the process is complete. In some embodiments, the corrective action includes providing feedback control (e.g., modifying a manufacturing parameter responsive to the predictive data 168 indicating a predicted abnormality). In some embodiments, performance of the corrective action includes causing updates to one or more manufacturing parameters. In some embodiments performance of a corrective action may include retraining a machine learning model associated with manufacturing equipment 124. In some embodiments, performance of a corrective action may include training a new machine learning model associated with manufacturing equipment 124. In some embodiments, performance of a corrective action may include recalibration of a physics-based model. In some embodiments, performance of a corrective action may include providing an indication of anomalous data to a user, e.g., via a graphical user interface (GUI).

Manufacturing parameters 150 may include hardware parameters (e.g., information indicative of which components are installed in manufacturing equipment 124, indicative of previously performed component replacements performed, indicative of component age, indicative of software version or updates, etc.) and/or process parameters (e.g., temperature, pressure, flow, rate, electrical current, voltage, gas flow, lift speed, etc.). In some embodiments, the corrective action includes causing preventative operative maintenance (e.g., replace, process, clean, etc. components of the manufacturing equipment 124). In some embodiments, the corrective action includes causing design optimization (e.g., updating manufacturing parameters, manufacturing processes, manufacturing equipment 124, etc. for an optimized product). In some embodiments, the corrective action includes a updating a recipe (e.g., altering the timing of manufacturing subsystems entering an idle or active mode, altering set points of various property values, etc.).

Model hosting server 112, server machine 170, and server machine 180 may each include one or more computing devices such as a rackmount server, a router computer, a server computer, a personal computer, a mainframe computer, a laptop computer, a tablet computer, a desktop computer, Graphics Processing Unit (GPU), accelerator Application- Specific Integrated Circuit (ASIC) (e.g., Tensor Processing Unit (TPU)), etc. Computing techniques may include edge computing. Operations of model hosting server 112, server machine 170, server machine 180, data store 140, etc., may be performed by a cloud computing service, cloud data storage service, etc.

Model hosting server 112 may include a predictive component 114. In some embodiments, the predictive component 114 may receive current sensor data 146, current manufacturing parameters, and/or simulation parameters associated with manufacturing parameters (e.g., receive from the client device 120, retrieve from the data store 140) and generate output (e.g., predictive data 168) for performing corrective action associated with the manufacturing equipment 124 based on the input data. In some embodiments, predictive data 168 may include one or more predicted dimension measurements of a processed product. In some embodiments, predictive component 114 may use one or more trained machine learning models 190 to determine the output for performing the corrective action based on current data. In some embodiments, predictive component 114 may utilize one or more physics-based models. In some embodiments, predictive component 114 may utilize one or more statistical, heuristic, rule-based, or other types of models for generating predictive data 168.

Manufacturing equipment 124 may be associated with one or more machine leaning models, e.g., model 190. Machine learning models associated with manufacturing equipment 124 may perform many tasks, including process control, classification, performance predictions, etc. Model 190 may be trained using data associated with manufacturing equipment 124 or products processed by manufacturing equipment 124, e.g., sensor data 142 (e.g., collected by sensors 126), manufacturing parameters 150 (e.g., associated with process control of manufacturing equipment 124), metrology data 160 (e.g., generated by metrology equipment 128), etc. Other types of models may operate similarly, e.g., a physics-based model associated with manufacturing equipment 124 may be calibrated using data associated with manufacturing equipment 124 in a similar manner to training a machine learning model (e.g., updating one or more parameters of the model based on an error term between output and target output of the model). In some embodiments, calibrating a physics-based model may consume far less data than training a machine learning model.

One type of machine learning model that may be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs).

A recurrent neural network (RNN) is another type of machine learning model. A recurrent neural network model is designed to interpret a series of inputs where inputs are intrinsically related to one another, e.g., time trace data, sequential data, etc. Output of a perceptron of an RNN is fed back into the perceptron as input, to generate the next output.

Deep learning is a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. In an image recognition application, for example, the raw input may be a matrix of pixels; the first representational layer may abstract the pixels and encode edges; the second layer may compose and encode arrangements of edges; the third layer may encode higher level shapes (e.g., teeth, lips, gums, etc.); and the fourth layer may recognize a scanning role. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

In some embodiments, a user utilizes a process modeling platform to provide predictive component 114 with current sensor data 146, current metrology data 162, current manufacturing parameters 152, and/or simulation parameters which may correspond to one or more of these data types. Predictive component 114 may the perform signal processing to break down the current data into sets of current data, provide the sets of current data as input to a trained model 190, and obtain outputs indicative of predictive data 168 from the trained model 190. In some embodiments, predictive component 114 receives metrology data (e.g., predicted metrology data based on sensor data) of a substrate and provides the metrology data to trained model 190. For example, current sensor data 146 may include sensor data indicative of metrology (e.g., geometry) of a substrate and/or other patterns of features or structures of the substrate. Model 190 may be configured to accept data indicative of substrate metrology and generate as output a set of process inputs predicted to result in a substrate with the target geometry.

In some embodiments, the various models discussed in connection with model 190 (e.g., supervised machine learning model, unsupervised machine learning model, physics-based digital twin model, etc.) may be combined in one model (e.g., an ensemble model), or may be separate models.

Data may be passed back and forth between several distinct models included in model 190, and predictive component 114. In some embodiments, some or all of these operations may instead be performed by a different device, e.g., client device 120, server machine 170, server machine 180, etc. It will be understood by one of ordinary skill in the art that variations in data flow, which components perform which processes, which models are provided with which data, and the like are within the scope of this disclosure.

Data store 140 may be a memory (e.g., random access memory), a drive (e.g., a hard drive, a flash drive), a database system, a cloud-accessible memory system, or another type of component or device capable of storing data. Data store 140 may include multiple storage components (e.g., multiple drives or multiple databases) that may span multiple computing devices (e.g., multiple server computers). The data store 140 may store sensor data 142, manufacturing parameters 150, metrology data 160, control data 169, and predictive data 168.

Sensor data 142 may include historical sensor data 144 and current sensor data 146. Sensor data may include sensor data time traces over the duration of manufacturing processes, associations of data with physical sensors, pre-processed data, such as averages and composite data, and data indicative of sensor performance over time (i.e., many manufacturing processes). Manufacturing parameters 150 and metrology data 160 may contain similar features, e.g., historical metrology data 162 and current metrology data 164. Historical sensor data 144, historical metrology data 162, and historical manufacturing parameters 152 may be historical data (e.g., at least a portion of these data may be used for training or calibrating model 190). Current sensor data 146, current metrology data 164, may be current data (e.g., at least a portion to be input into model 190, subsequent to the historical data) for which predictive data 168 is to be generated (e.g., for performing corrective actions).

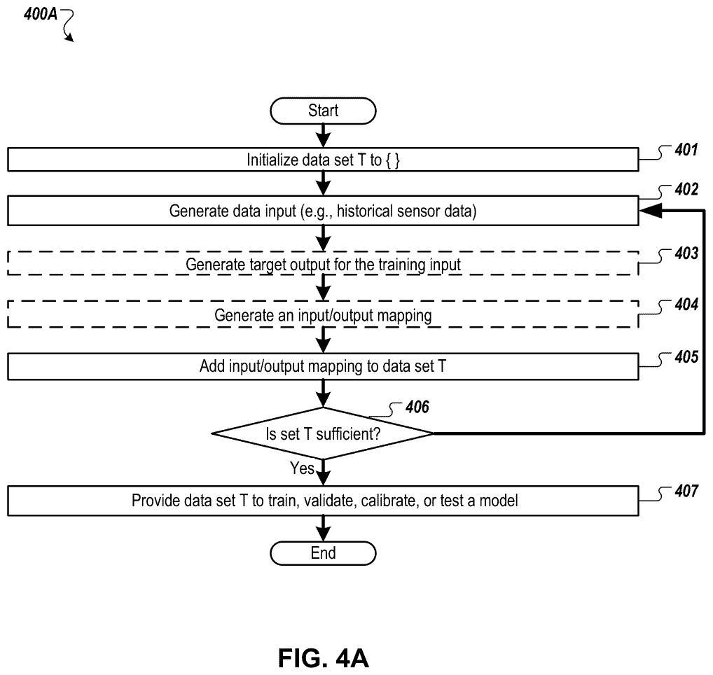

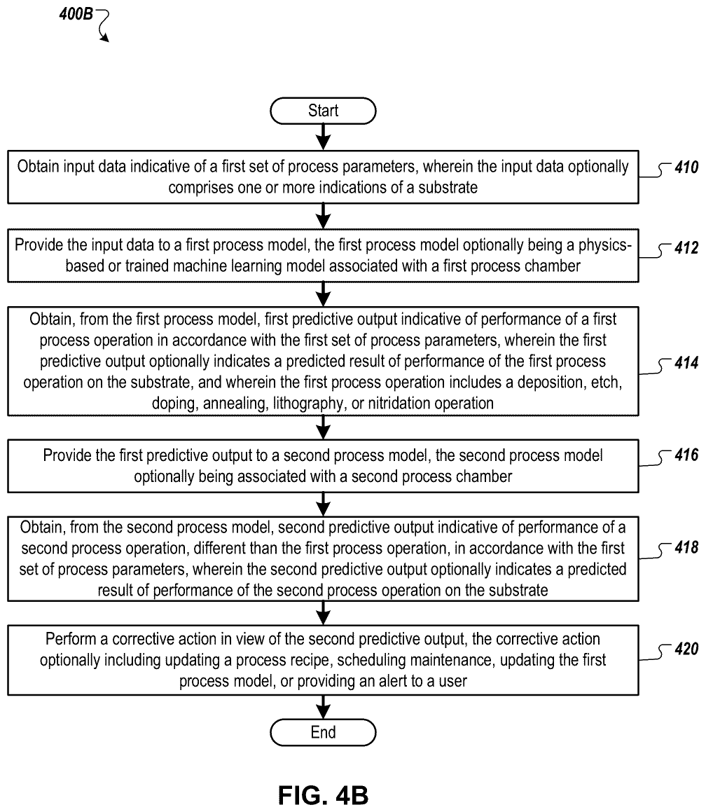

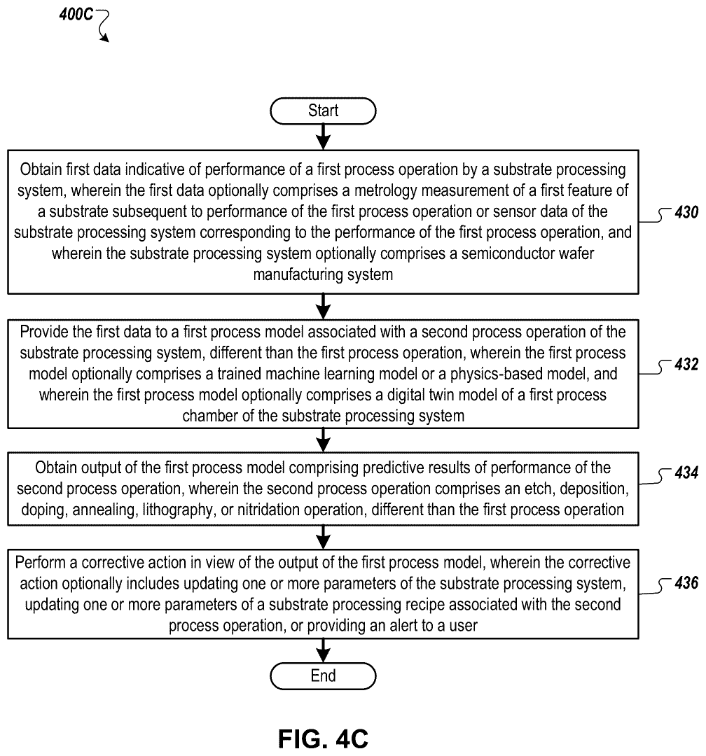

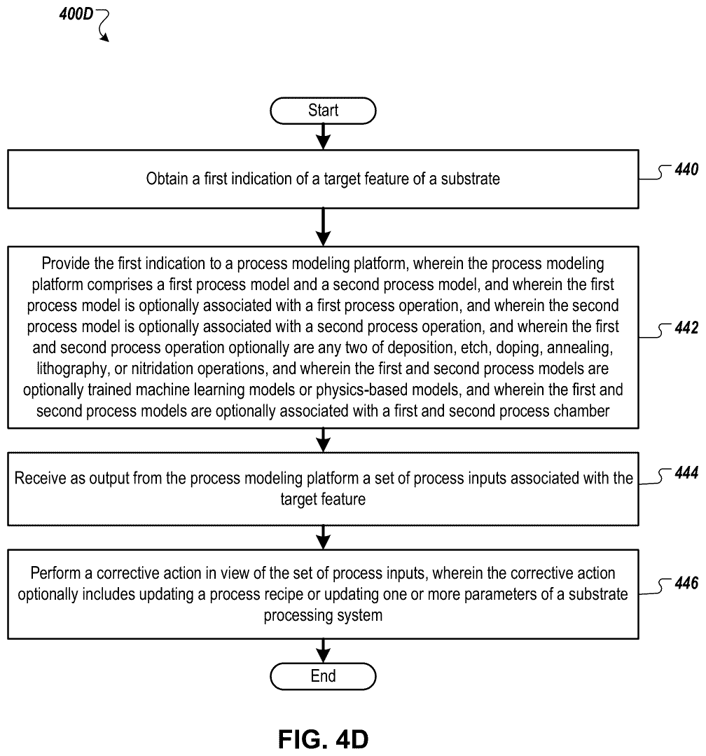

In some embodiments, predictive system 110 further includes server machine 170 and server machine 180. Server machine 170 includes a data set generator 172 that is capable of generating data sets (e.g., a set of data inputs and a set of target outputs) to train, validate, and/or test model(s) 190, including one or more machine learning models. Some operations of data set generator 172 are described in detail below with respect to FIG. 4A. In some embodiments, data set generator 172 may partition the historical data (e.g., historical sensor data 144, historical manufacturing parameters, historical metrology data) into a training set (e.g., sixty percent of the historical data), a validating set (e.g., twenty percent of the historical data), and a testing set (e.g., twenty percent of the historical data).

In some embodiments, predictive system 110 (e.g., via predictive component 114) generates multiple sets of features. For example a first set of features may correspond to a first set of types of sensor data (e.g., from a first set of sensors, first combination of values from first set of sensors, first patterns in the values from the first set of sensors) that correspond to each of the data sets (e.g., training set, validation set, and testing set) and a second set of features may correspond to a second set of types of sensor data (e.g., from a second set of sensors different from the first set of sensors, second combination of values different from the first combination, second patterns different from the first patterns) that correspond to each of the data sets.

In some embodiments, model 190 is provided historical data as training data (e.g., in the case of a machine learning model). In some embodiments, model 190 is provided historical data as calibration data (e.g., in the case of a physics-based model). The type of data provided will vary depending on the intended use of the model. For example, a machine learning model may be trained by providing the model with historical sensor data 144 as training input and corresponding metrology data 160 as target output. In some embodiments, a large volume of data is used to train model 190, e.g., sensor and metrology data of hundreds of substrates may be used. In some embodiments, a fairly small volume of data may be used to calibrate a physics-based model 190.

Server machine 180 includes a training engine 182, a validation engine 184, selection engine 185, and/or a testing engine 186. An engine (e.g., training engine 182, a validation engine 184, selection engine 185, and a testing engine 186) may refer to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine 182 may be capable of training or calibrating a model 190 using one or more sets of features associated with the training set from data set generator 172. The training engine 182 may generate multiple trained models 190, where each trained model 190 corresponds to a distinct set of features of the training set (e.g., sensor data from a distinct set of sensors). For example, a first trained model may have been trained using all features (e.g., X1-X5), a second trained model may have been trained using a first subset of the features (e.g., X1, X2, X4), and a third trained model may have been trained using a second subset of the features (e.g., X1, X3, X4, and X5) that may partially overlap the first subset of features.

Validation engine 184 may be capable of validating a trained model 190 using a corresponding set of features of the validation set from data set generator 172. For example, a first trained machine learning model 190 that was trained using a first set of features of the training set may be validated using the first set of features of the validation set. The validation engine 184 may determine an accuracy of each of the trained models 190 based on the corresponding sets of features of the validation set. Validation engine 184 may discard trained models 190 that have an accuracy that does not meet a threshold accuracy. In some embodiments, selection engine 185 may be capable of selecting one or more trained models 190 that have an accuracy that meets a threshold accuracy. In some embodiments, selection engine 185 may be capable of selecting the trained model 190 that has the highest accuracy of the trained models 190.

Testing engine 186 may be capable of testing a trained model 190 using a corresponding set of features of a testing set from data set generator 172. For example, a first trained machine learning model 190 that was trained using a first set of features of the training set may be tested using the first set of features of the testing set. Testing engine 186 may determine a trained model 190 that has the highest accuracy of all of the trained models based on the testing sets.

In the case of a machine learning model, model 190 may refer to the model artifact that is created by training engine 182 using a training set that includes data inputs and corresponding target outputs (correct answers for respective training inputs). Patterns in the data sets can be found that map the data input to the target output (the correct answer), and machine learning model 190 is provided mappings that capture these patterns. The machine learning model 190 may use one or more of Support Vector Machine (SVM), Radial Basis Function (RBF), clustering, supervised machine learning, semi-supervised machine learning, unsupervised machine learning, k-Nearest Neighbor algorithm (k-NN), linear regression, random forest, neural network (e.g., artificial neural network, recurrent neural network), etc.

Predictive component 114 may provide input data to model 190 and may run model 190 on the input to obtain one or more outputs. For example, predictive component 114 may provide current sensor data 146 to model 190 and may run model 190 on the input to obtain one or more outputs. Predictive component 114 may provide simulation input data (e.g., user-defined simulation input data) to model 190, model 190 may model a number of process operations including different types of process operations, physics-based models, data-based models, etc., and a predictive output related to the simulation input may be generated. In some embodiments, predictive component 114 may be provided with input data, and generate, by providing the input data to one or more process models, an input/output mapping determining correspondences between the input data and the generated output data. In some embodiments, predictive component 114 may be provided with data indicative of progress of a substrate processing operation (e.g., sensor data or metrology data indicative of processing in progress), and model 190 may be utilized to generate output indicative of adjustments to subsequent process operations to be performed to satisfy target performance metrics.

Predictive component 114 may be capable of determining (e.g., extracting) predictive data 168 from the output of model 190. Predictive component 114 may determine (e.g., extract) confidence data from the output that indicates a level of confidence that predictive data 168 is an accurate predictor of a process associated with the input data for products produced or to be produced using the manufacturing equipment 124 at the current sensor data 146 and/or current manufacturing parameters. Predictive component 114 or corrective action component 122 may use the confidence data to decide whether to cause a corrective action associated with the manufacturing equipment 124 based on predictive data 168.

The confidence data may include or indicate a level of confidence that the predictive data 168 is an accurate prediction for products or components associated with at least a portion of the input data. In one example, the level of confidence is a real number between 0 and 1 inclusive, where 0 indicates no confidence that the predictive data 168 is an accurate prediction for products processed according to input data or component health of components of manufacturing equipment 124 and 1 indicates absolute confidence that the predictive data 168 accurately predicts properties of products processed according to input data or component health of components of manufacturing equipment 124. Responsive to the confidence data indicating a level of confidence below a threshold level for a predetermined number of instances (e.g., percentage of instances, frequency of instances, total number of instances, etc.) predictive component 114 may cause trained model 190 to be re-trained (e.g., based on current sensor data 146, current manufacturing parameters, etc.). In some embodiments, retraining may include generating one or more data sets (e.g., via data set generator 172) utilizing historical data.

For purpose of illustration, rather than limitation, aspects of the disclosure describe the training of one or more machine learning models 190 using historical data (e.g., historical sensor data 144, historical manufacturing parameters 152) and inputting current data (e.g., current sensor data 146, current manufacturing parameters, and current metrology data) into the one or more trained machine learning models to determine predictive data 168. In other embodiments, a heuristic model, physics-based model, or rule-based model is used to determine predictive data 168 (e.g., without using a trained machine learning model). In some embodiments, such models may be trained using historical data. Predictive component 114 may monitor historical sensor data 144, historical manufacturing parameters 152, and metrology data 160.

In some embodiments, the functions of client device 120, model hosting server 112, server machine 170, and server machine 180 may be provided by a fewer number of machines. For example, in some embodiments server machines 170 and 180 may be integrated into a single machine, while in some other embodiments, server machine 170, server machine 180, and model hosting server 112 may be integrated into a single machine. In some embodiments, client device 120 and model hosting server 112 may be integrated into a single machine. In some embodiments, functions of client device 120, model hosting server 112, server machine 170, server machine 180, and data store 140 may be performed by a cloud-based service.

In general, functions described in one embodiment as being performed by client device 120, model hosting server 112, server machine 170, and server machine 180 can also be performed on model hosting server 112 in other embodiments, if appropriate. In addition, the functionality attributed to a particular component can be performed by different or multiple components operating together. For example, in some embodiments, the model hosting server 112 may determine the corrective action based on the predictive data 168. In another example, client device 120 may determine the predictive data 168 based on output from the trained machine learning model.

In addition, the functions of a particular component can be performed by different or multiple components operating together. One or more of the model hosting server 112, server machine 170, or server machine 180 may be accessed as a service provided to other systems or devices through appropriate application programming interfaces (API).

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

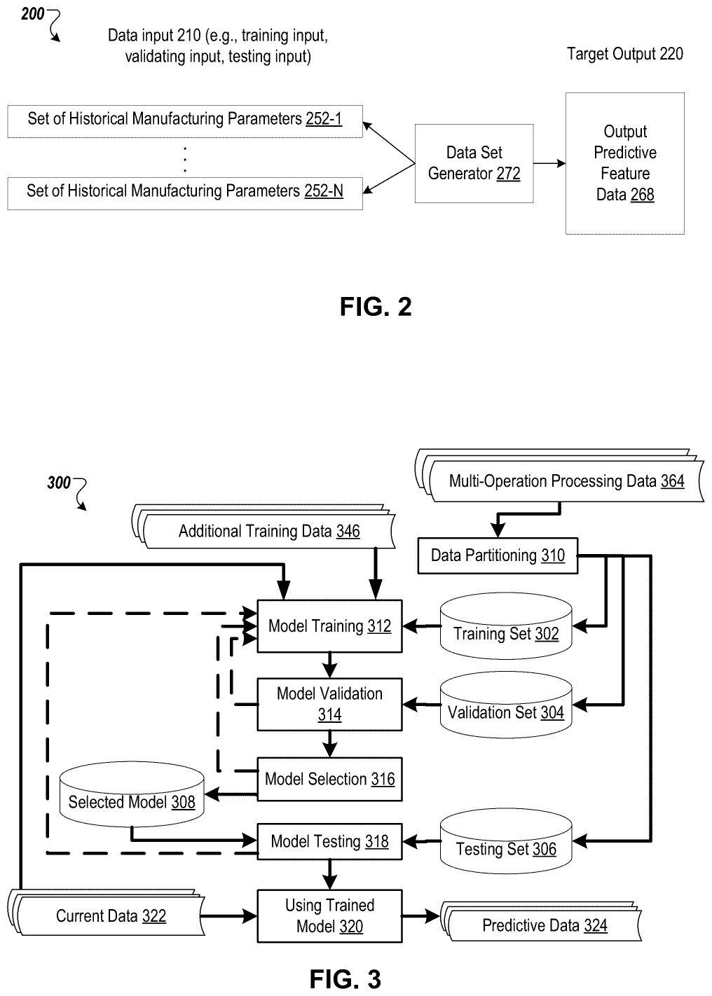

FIG. 2 depicts a block diagram of example data set generator 272 (e.g., data set generator 172 of FIG. 1) to create data sets for training, testing, validating, calibrating, etc. a model (e.g., model 190 of FIG. 1), according to some embodiments. Each data set generator 272 may be part of server machine 170 of FIG. 1. In some embodiments, data set generator 272 may generate data sets to be utilized to adjust, validate, test, or the like a physics-based model or reduced order model. In some embodiments, data set generator 272 may generate data sets to be utilized in generating, validating, etc., machine learning models in association with the manufacturing equipment. In some embodiments, several models associated with manufacturing equipment 124 may be trained, used, and maintained (e.g., within a manufacturing facility). One or more physics-based models, one or more reduced order models, and/or one or more trained machine learning models may be generated and maintained in association with the manufacturing equipment. Each model may be associated with one data set generators 272, multiple models may share a data set generator 272, etc.

FIG. 2 depicts a system 200 including data set generator 272 for creating data sets for one or more supervised models (e.g., including data associated with input to a model and output from the model). Data set generator 272 may create data sets (e.g., data input 210, target output 220) using historical data, which may include manufacturing parameters, metrology data, classification data, substrate property data, simulation inputs related to manufacturing parameters, or the like. In some embodiments, a data set generator similar to data set generator 272 may be utilized to train an unsupervised model, e.g., target output 220 may not be generated by data set generator 272.

Data set generator 272 may generate data sets to train, test, and validate a model, e.g., a machine learning model. Data set generator 272 may generate data sets to calibrate a model, e.g., a physics-based model (including reduced order models). In some embodiments, data set generator 272 may generate data sets for a machine learning model. In some embodiments, data set generator 272 may generate data sets for training, testing, and/or validating a model configured to predict properties of a substrate. In some embodiments, data set generator 272 may generate data sets for training, testing, and/or validating a model that is used as part of a comprehensive modeling platform. For example, many models representing different types of processes, different process chambers, different process materials, different process conditions, or the like may be generated, and these models used together to generate predictions of complex, multi-step processes for producing substrate products. A single substrate may undergo many types of operations in many different process chambers, which may include enacting hundreds of recipes from start of substrate processing until a finished substrate is developed. Outputs from one process step (e.g., measured, modeled, or simulated output) may be fed into a model as input for a subsequent or later operation. In some embodiments, models may be generated for performing optimization operations, for performing inverse operations compared to those described above, or the like. For example, the data set generator 272 may instead generate as data input 210 substrate properties (e.g., features, metrology, categorizations, etc.), to train a model to generate processing inputs that a predicted to generate a substrate exhibiting the target substrate properties.

A model to be generated (e.g., trained, calibrated, or the like) may be provided with a set of historical manufacturing parameters 252-1 as data input 210. The set of historical manufacturing parameters 252-1 may include process control set points. The set of historical manufacturing parameters 252-1 may include parameters determining actions of manufacturing equipment, such as ramp times for valve actuation. The model may be configured to accept indications of manufacturing parameters (e.g., current manufacturing parameters) as input and generate predictions related to substrate properties after processing as output.

Data set generator 272 may be used to generate data sets for any type of model used in association with predicting or correcting substrate properties. Data set generator 272 may be used to generate data for any type of machine learning model that takes as input historical manufacturing parameter data. A data set generator analogous to data set generator 272 may be used to generate data for any type of model that takes as input target substrate properties and generates as output predicted process parameters associated with producing a substrate exhibiting the target properties. Data set generator 272 may be used to generate data for a machine learning model configured to provide process update instructions, e.g., configured to update manufacturing parameters, manufacturing recipes, equipment constants, or the like. Data set generator 272 may be used to generate data for a machine learning model configured to identify a product anomaly and/or processing equipment fault.

In some embodiments, data set generator 272 generates a data set (e.g., training set, validating set, testing set) that includes one or more data inputs 210 (e.g., training input, validating input, testing input). Data inputs 210 may be provided to training engine 182, validating engine 184, or testing engine 186. The data set may be used to train, validate, or test the model (e.g., model 190 of FIG. 1).

In some embodiments, data input 210 may include one or more sets of data. As an example, system 200 may produce sets of manufacturing parameter data that may include one or more of parameter data from one or more types of components, combinations of parameter data from one or more types of components, patterns from parameter data from one or more types of components, or the like. In some embodiments, target output 220 may include sets of output related to the various sets of data input 210.

In some embodiments, data set generator 272 may generate a first data input corresponding to a first set of manufacturing parameters 252-1 to train, validate, or test a first machine learning model. Data set generator 272 may generate a second data input corresponding to a second set of historical manufacturing parameter data (e.g., a set of historical metrology data 252-2, not shown) to train, validate, or test a second machine learning model. Further sets of historical data may further be utilized in generating further machine learning models. Any number of sets of historical data may be utilized in generating any number of machine learning models, up to a final set, set of historical manufacturing parameters 252-N (N representing any target quantity of data sets, models, etc.)

In some embodiments, data set generator 272 may generate a first data input corresponding to a first set of historical manufacturing parameters 252-1 to train, validate, or test a first machine learning model. Data set generator 272 may generate a second data input corresponding to a second set of historical manufacturing parameters 252-2 (not shown) to train, validate, or test a second machine learning model. Analogous sets of data may be generated based on substrate properties as training input for training a model to predict process parameters to be used in producing a substrate exhibiting the target properties.

In some embodiments, data set generator 272 generates a data set (e.g., training set, validating set, testing set) that includes one or more data inputs 210 (e.g., training input, validating input, testing input) and may include one or more target outputs 220 that correspond to the data inputs 210. The data set may also include mapping data that maps the data inputs 210 to the target outputs 220. In some embodiments, data set generator 272 may generate data for training a model configured to output data indicative of substrate properties, output predictive feature data 268. Data inputs 210 may also be referred to as “features,” “attributes,” or “information.” In some embodiments, data set generator 272 may provide the data set to training engine 182, validating engine 184, or testing engine 186, where the data set is used to train, validate, or test the model (e.g., one of the machine learning models that are included in model 190, ensemble model 190, etc.).

In some embodiments, subsequent to generating a data set and training, validating, or testing a machine learning model using the data set, the model may be further trained, validated, or tested, or adjusted (e.g., adjusting weights or parameters associated with input data of the model, such as connection weights in a neural network).

FIG. 3 is a block diagram illustrating system 300 for generating output data (e.g., predictive data 168 of FIG. 1), according to some embodiments. In some embodiments, system 300 may be used in conjunction with a model (e.g., physics-based, reduced order, data-based, machine learning, or the like) configured to generate predictive data related to particle defect generation. In some embodiments, system 300 is utilized for generating output data by a model such as model 190 of FIG. 1. In some embodiments, system 300 may be used in conjunction with a model to determine a corrective action associated with manufacturing equipment. In some embodiments, system 300 may be used in conjunction with a model to determine a fault of manufacturing equipment, e.g., a component resulting in particles being deposited on substrates during processing operations. In some embodiments, system 300 may be used in conjunction with a machine learning model to cluster or classify substrates or substrate defects. System 300 may be used in conjunction with a machine learning model with a different function than those listed, associated with a manufacturing system.

At block 310, system 300 (e.g., components of predictive system 110 of FIG. 1) performs data partitioning (e.g., via data set generator 172 of server machine 170 of FIG. 1) of data to be used in training, validating, and/or testing a model, such as a machine learning model. Multi-operation processing data 364 may include data associated with performance of one or more operations of a multi-step processing procedure, which may include cyclic procedures, performance of different types of procedures, performance in different process chambers, etc. Multi-operation processing data 364 is an example data type, analogous procedures may be performed with single-operation processes for generating predictive data, according to some embodiments. In some embodiments, multi-operation processing data 364 includes historical data, such as historical metrology data (e.g., properties and/or features of historical substrates), historical manufacturing parameter data, historical classification data (e.g., classification of properties of substrates, such as presence of a void in a gapfill application), measured chamber condition data (e.g., indicative of backflow), etc. In some embodiments, e.g., when utilizing physics-based model data to train a machine learning model, multi-operation processing data 364 may include data output by a physics-based model (e.g., a computationally expensive computational fluid dynamics model). Multi-operation processing data 364 may undergo data partitioning at block 310 to generate training set 302, validation set 304, and testing set 306. For example, the training set may be 60% of the training data, the validation set may be 20% of the training data, and the testing set may be 20% of the training data.

The generation of training set 302, validation set 304, and testing set 306 may be tailored for a particular application. For example, the training set may be 60% of the training data, the validation set may be 20% of the training data, and the testing set may be 20% of the training data. System 300 may generate a plurality of sets of features for each of the training set, the validation set, and the testing set. For example, if multi-operation processing data 364 includes manufacturing parameters, including features derived from 20 recipe parameters and 10 hardware parameters, the data may be divided into a first set of features including recipe parameters 1-10 and a second set of features including recipe parameters 11-20. The hardware parameters may also be divided into sets, for instance a first set of hardware parameters including parameters 1-5, and a second set of hardware parameters including parameters 6-10. Either target input, target output, both, or neither may be divided into sets. Multiple models may be trained on different sets of data.

At block 312, system 300 performs model training (e.g., via training engine 182 of FIG. 1) using training set 302. Training of a machine learning model and/or of a physics-based model (e.g., a digital twin) may be achieved in a supervised learning manner, which involves providing a training dataset including labeled inputs through the model, observing its outputs, defining an error (by measuring the difference between the outputs and the label values), and using techniques such as deep gradient descent and backpropagation to tune the weights of the model such that the error is minimized. In many applications, repeating this process across the many labeled inputs in the training dataset yields a model that can produce correct output when presented with inputs that are different than the ones present in the training dataset. In some embodiments, training of a machine learning model may be achieved in an unsupervised manner, e.g., labels or classifications may not be supplied during training. An unsupervised model may be configured to perform anomaly detection, result clustering, etc.

For each training data item in the training dataset, the training data item may be input into the model (e.g., into the machine learning model). The model may then process the input training data item (e.g., one or more manufacturing parameter values, etc.) to generate an output. The output may include, for example, substrate features or metrology, substrate defect generation rates, or the like. The output may be compared to a label of the training data item (e.g., a measured defect likelihood or measured/modeled substrate properties).

Processing logic may then compare the generated output (e.g., predicted substrate properties) to the label (e.g., actual substrate properties) that was included in the training data item. Processing logic determines an error (i.e., a classification error) based on the differences between the output and the label(s). Processing logic adjusts one or more weights and/or values of the model based on the error. Analogous operations may be performed for a machine learning model that performs different operations, e.g., a machine learning model that takes as input target substrate features and generates as output process parameters predicted to be utilized in generating a substrate exhibiting the target features.

In the case of training a neural network, an error term or delta may be determined for each node in the artificial neural network. Based on this error, the artificial neural network adjusts one or more of its parameters for one or more of its nodes (the weights for one or more inputs of a node). Parameters may be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters may include adjusting the weights assigned to each of the inputs for one or more neurons at one or more layers in the artificial neural network.

System 300 may train multiple models using multiple sets of features of the training set 302 (e.g., a first set of features of the training set 302, a second set of features of the training set 302, etc.). For example, system 300 may train a model to generate a first trained model using the first set of features in the training set (e.g., manufacturing parameter data from components 1-10, condition predictions 1-10, etc.) and to generate a second trained model using the second set of features in the training set (e.g., manufacturing parameter data from components 11-20, modeling process chamber conditions 11-20, etc.). In some embodiments, the first trained model and the second trained model may be combined to generate a third trained model (e.g., which may be a better predictor than the first or the second trained model on its own). In some embodiments, sets of features used in comparing models may overlap (e.g., first set of features being parameters 1-15 and second set of features being parameters 5-20). In some embodiments, hundreds of models may be generated including models with various permutations of features and combinations of models.

At block 314, system 300 performs model validation (e.g., via validation engine 184 of FIG. 1) using the validation set 304. The system 300 may validate each of the trained models using a corresponding set of features of the validation set 304. For example, system 300 may validate the first trained model using the first set of features in the validation set (e.g., parameters 1-10 or conditions 1-10) and the second trained model using the second set of features in the validation set (e.g., parameters 11-20 or conditions 11-20). In some embodiments, system 300 may validate hundreds of models (e.g., models with various permutations of features, combinations of models, etc.) generated at block 312. At block 314, system 300 may determine an accuracy of each of the one or more trained models (e.g., via model validation) and may determine whether one or more of the trained models has an accuracy that meets a threshold accuracy. Responsive to determining that none of the trained models has an accuracy that meets a threshold accuracy, flow returns to block 312 where the system 300 performs model training using different sets of features of the training set. Responsive to determining that one or more of the trained models has an accuracy that meets a threshold accuracy, flow continues to block 316. System 300 may discard the trained models that have an accuracy that is below the threshold accuracy (e.g., based on the validation set).

At block 316, system 300 performs model selection (e.g., via selection engine 185 of FIG. 1) to determine which of the one or more trained models that meet the threshold accuracy has the highest accuracy (e.g., the selected model 308, based on the validating of block 314). Responsive to determining that two or more of the trained models that meet the threshold accuracy have the same accuracy, flow may return to block 312 where the system 300 performs model training using further refined training sets corresponding to further refined sets of features for determining a trained model that has the highest accuracy.

At block 318, system 300 performs model testing (e.g., via testing engine 186 of FIG. 1) using testing set 306 to test selected model 308. System 300 may test, using the first set of features in the testing set (e.g., parameters 1-10), the first trained model to determine the first trained model meets a threshold accuracy. Determining whether the first trained model meets a threshold accuracy may be based on the first set of features of testing set 306. Responsive to accuracy of the selected model 308 not meeting the threshold accuracy, flow continues to block 312 where system 300 performs model training (e.g., retraining) using different training sets corresponding to different sets of features. Accuracy of selected model 308 may not meet threshold accuracy if selected model 308 is overly fit to the training set 302 and/or validation set 304. Accuracy of selected model 308 may not meet threshold accuracy if selected model 308 is not applicable to other data sets, including testing set 306. Training using different features may include training using data from different sensors, different manufacturing parameters, etc. Responsive to determining that selected model 308 has an accuracy that meets a threshold accuracy based on testing set 306, flow continues to block 320. In at least block 312, the model may learn patterns in the training data to make predictions. In block 318, the system 300 may apply the model on the remaining data (e.g., testing set 306) to test the predictions.

At block 320, system 300 uses the trained model (e.g., selected model 308) to receive current data 322 and determines (e.g., extracts), from the output of the trained model, predictive data 324. Current data 322 may be manufacturing parameters related to a process, operation, or action of interest. Current data 322 may be manufacturing parameters related to a process under development, redevelopment, investigation, etc. Current data 322 may be manufacturing parameters related to one or more type of processing, including deposition, etch, annealing, nitridation, lithography, etc. Current data 322 may be manufacturing parameters that may have an effect on delay of changes to condition values compared to initiation of condition-altering actions. A corrective action associated with the manufacturing equipment 124 of FIG. 1 may be performed in view of predictive data 324. In some embodiments, current data 322 may correspond to the same types of features in the historical data used to train the machine learning model. In some embodiments, current data 322 corresponds to a subset of the types of features in historical data that are used to train selected model 308. For example, a machine learning model may be trained using a number of manufacturing parameters, and configured to generate output based on a subset of the manufacturing parameters.

In some embodiments, the performance of a machine learning model trained, validated, and tested by system 300 may deteriorate. For example, a manufacturing system associated with the trained machine learning model may undergo a gradual change or a sudden change. A change in the manufacturing system may result in decreased performance of the trained machine learning model. A new model may be generated to replace the machine learning model with decreased performance. The new model may be generated by altering the old model by retraining, by generating a new model, etc.

Generation of a new model may include providing additional training data 346. Generation of a new model may further include providing current data 322, e.g., data that has been used by the model to make predictions. In some embodiments, current data 322 when provided for generation of a new model may be labeled with an indication of an accuracy of predictions generated by the model based on current data 322. Additional training data 346 may be provided to model training of block 312 for generation of one or more new machine learning models, updating, retraining, and/or refining of selected model 308, etc.

In some embodiments, one or more of the acts 310-320 may occur in various orders and/or with other acts not presented and described herein. In some embodiments, one or more of acts 310-320 may not be performed. For example, in some embodiments, one or more of data partitioning of block 310, model validation of block 314, model selection of block 316, or model testing of block 318 may not be performed.

FIG. 3 depicts a system configured for training, validating, testing, and using one or more machine learning models. The machine learning models are configured to accept data as input (e.g., set points provided to manufacturing equipment, sensor data, metrology data, etc.) and provide data as output (e.g., predictive data, corrective action data, classification data, etc.). Partitioning, training, validating, selection, testing, and using blocks of system 300 may be executed similarly to train a second model, utilizing different types of data. Retraining may also be performed, utilizing current data 322 and/or additional training data 346.

FIGS. 4A-D are flow diagrams of methods 400A-D associated with training and utilizing a process modeling platform, according to some embodiments. Methods 400A-D may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiment, methods 400A-D may be performed, in part, by predictive system 110. Method 400A may be performed, in part, by predictive system 110 (e.g., server machine 170 and data set generator 172 of FIG. 1). Predictive system 110 may use method 400A to generate a data set to at least one of train, validate, or test a machine learning model, in accordance with embodiments of the disclosure. Predictive system 110 may use method 400A to generate a data set to calibrate a physics-based model. Predictive system 110 may use method 400A to generate a data set to configure another type of model for use by a comprehensive modeling platform in association with a process chamber. Methods 400B-D may be performed by model hosting server 112 (e.g., predictive component 114), client device 120, and/or server machine 180 (e.g., training, validating, and testing operations may be performed by server machine 180). In some embodiments, a non-transitory machine-readable storage medium stores instructions that when executed by a processing device (e.g., of predictive system 110, of server machine 180, of model hosting server 112, etc.) cause the processing device to perform one or more of methods 400A-C.

For simplicity of explanation, methods 400A-D are depicted and described as a series of operations. However, operations in accordance with this disclosure can occur in various orders and/or concurrently and with other operations not presented and described herein. Furthermore, not all illustrated operations may be performed to implement methods 400A-D in accordance with the disclosed subject matter. In addition, those skilled in the art will understand and appreciate that methods 400A-D could alternatively be represented as a series of interrelated states via a state diagram or events.

FIG. 4A is a flow diagram of a method 400A for generating a data set for a model, according to some embodiments. The data set may be utilized in training, validating, or testing a model. The data set may be generated for a machine learning model. The data set may be generated for calibrating a physics-based model. The data set may be for generating a digital twin model of a process chamber. The data set may be utilized for configuring another type of model in association with a process chamber. The data set may be utilized for generating a model to be used in association with a process modeling platform for modeling portions of a multi-operation processing procedure. Referring to FIG. 2A, in some embodiments, at block 401 the processing logic implementing method 400A initializes a training set T to an empty set.

At block 402, processing logic generates first data input (e.g., first training input, first validating input) that may include one or more of sensor, manufacturing parameters, metrology data, etc. In some embodiments, the first data input may include a first set of features for types of data and a second data input may include a second set of features for types of data. Input data may include historical data.

In some embodiments, at block 403, processing logic optionally generates a first target output for one or more of the data inputs (e.g., first data input). In some embodiments, the input includes one or more process modeling or simulation inputs and the target output includes substrate feature data. In some embodiments, the input includes one or more indications of an input substrate to a process (which may be generated as output from another model) and target output includes substrate feature data. In some embodiments, input includes one or more indications of substrate processing operations (e.g., sensor data of one or more substrate processing operations, metrology data of a substrate in processing, etc.), and the target output includes one or more process parameters for subsequent substrate processing operations for generating a target substrate feature. In some embodiments, input may include one or more target substrate features, and target output includes process and/or simulation parameters predicted to result in a substate meeting target feature conditions. In some embodiments, the first target output is predictive data. In some embodiments, input data may be in the form of sensor data and target output may be a list of components likely to be faulty, as in the case of a machine learning model configured to identify failing manufacturing systems. In some embodiments, no target output is generated (e.g., an unsupervised machine learning model capable of grouping or finding correlations in input data, rather than requiring target output to be provided).

At block 404, processing logic optionally generates mapping data that is indicative of an input/output mapping. The input/output mapping (or mapping data) may refer to the data input (e.g., one or more of the data inputs described herein), the target output for the data input, and an association between the data input(s) and the target output. In some embodiments, such as in association with machine learning models where no target output is provided, block 404 may not be executed.

At block 405, processing logic adds the mapping data generated at block 404 to data set T, in some embodiments.

At block 406, processing logic branches based on whether data set T is sufficient for at least one of training, validating, and/or testing a machine learning model, calibrating a physics-based model, configuring another type of model, or the like. If so, execution proceeds to block 407, otherwise, execution continues back at block 402. It should be noted that in some embodiments, the sufficiency of data set T may be determined based simply on the number of inputs, mapped in some embodiments to outputs, in the data set, while in some other embodiments, the sufficiency of data set T may be determined based on one or more other criteria (e.g., a measure of diversity of the data examples, accuracy, etc.) in addition to, or instead of, the number of inputs.

At block 407, processing logic provides data set T (e.g., to server machine 180) to train, validate, calibrate and/or test model 190. Model 190 may be a machine learning model. Model 190 may be a physics-based model. In some embodiments, data set T is a training set and is provided to training engine 182 of server machine 180 to perform the training. In some embodiments, data set T is a validation set and is provided to validation engine 184 of server machine 180 to perform the validating. In some embodiments, data set T is a testing set and is provided to testing engine 186 of server machine 180 to perform the testing. In the case of a neural network, for example, input values of a given input/output mapping are input to the neural network, and output values of the input/output mapping are stored in the output nodes of the neural network. The connection weights in the neural network are then adjusted in accordance with a learning algorithm (e.g., back propagation, etc.), and the procedure is repeated for the other input/output mappings in data set T. After block 407, a model (e.g., model 190) can be at least one of trained using training engine 182 of server machine 180, validated using validating engine 184 of server machine 180, or tested using testing engine 186 of server machine 180. The trained model may be implemented by predictive component 114 (of model hosting server 112) to generate predictive data 168 for performing signal processing, to generate synthetic data 162, or for performing a corrective action associated with manufacturing equipment 124.

FIG. 4B is a flow diagram of a method 400B for utilizing a process modeling platform for determining predictive data associated with a multi-operation substrate processing procedure, according to some embodiments. At block 410, processing logic obtains input data indicative of a first set of process parameters. The input data may be or include process recipe functions, manufacturing or hardware parameters, process parameters, or the like. In some embodiments, input data may include simulation parameters, e.g., parameters different than process inputs, that are related to process inputs, such as etch rate, deposition rate, or the like. The input data may include one or more indications of a substrate, such as sensor data (measured or virtual) related to a previously performed process operation, metrology data related to one or more characteristics or features of the substrate, or the like.

At block 412, processing logic provides the input data to a first process model. The first process model may be a physics-based model. The first process model may be a trained machine learning model. The first process model may be a digital twin model of a physical process chamber. The first process model may be chamber agnostic.

At block 414, processing logic obtains, from the first process model, first predictive output. The first predictive output may be indicative of performance of a first process operation in accordance with the first set of process parameters. The first predictive output may include a predicted result of performance of the first process operation on the substrate. The first process operation may be or include any type of substrate processing operation, such as a deposition, etch, doping, annealing, lithography, or nitridation operation.

At block 416, processing logic provides the first predictive output to a second process model. The second process model may share one or more features with the first process model. The second process model may be associated with a second process operation, second type of process operation, second process chamber, or the like.

At block 418, processing logic obtains, from the second process model, second predictive output indicative of performance of a second process operations, different than the first process operation. The second process model may be executed in accordance with the first set of process parameters. The second predictive output may optionally indicate a predicted result of performance of the second process operation on the substrate.

At block 420, processing logic performs a corrective action in view of the second predictive output. The corrective action may include updating a process recipe. The corrective action may include scheduling maintenance. The corrective action may include updating the first process model and/or the second process model. The corrective action may include providing an alert to a user.

FIG. 4C is a flow diagram of a method 400C for utilizing a process modeling platform for adjusting performance of one or more process operations, according to some embodiments. At block 430, processing logic obtains first data indicative of performance of a first process operation by a substrate processing system. The substrate processing system may be a semiconductor wafer manufacturing system. The performance of the first process operation may include processing of a substrate, such as performing a deposition, etch, doping, annealing, lithography, nitridation, or other operation of the substrate. The first data may include one or more metrology measurements of a substrate, including one or more metrology measurements of one or more target features of the substrate. The first data may include data from one or more measurements performed after performance of the first process operation. The first data may include sensor data from the substrate processing system corresponding to the performance of the first process operation.

At block 432, processing logic provides the first data to a first process model associated with a second process operation of the substrate processing system. The second process operation is different than the first process operation. The first process model may be or include a trained machine learning model. The first process model may be or include a physics-based model. The first process model may be or include a digital twin model of a first process chamber of the substrate processing system.

At block 434, processing logic obtains output of the first process model. The output may include predictive results of performance of the second process operation.

At block 436, processing logic performs a corrective action in view of the output of the first process model. In some embodiments, further models may be utilized. For example, a sequence of process models, each influenced by output of previous models, may be utilized. The sequence of process models may indicate an outcome, one or more substrate features, one or more substrate characteristics, or the like. The corrective action may be performed in further view of output of the sequence of process models. The corrective action may include updating one or more parameters of the substrate processing system. The corrective action may include updating one or more parameter of a substrate processing recipe associated with the second process operation (e.g., adjusting performance of future substrate processing operations to be performed on the substrate, for example to correct for unexpected process results, process results not satisfying a threshold performance condition, or the like). The corrective action may include providing an alert to a user.

FIG. 4D is a flow diagram of a method 400D for utilizing a process modeling platform for generating a substrate including target features, according to some embodiments. At block 440, processing logic obtains a first indication of a target feature of a substrate. The target feature may be any target characteristic of the substrate. The target feature may be geometrical, an optical property, electrical property, target roughness, material, critical dimension, or the like. The target feature may include a target value, a range of acceptable values, one or more target performance thresholds, or the like. Instead or additionally, the first indication may be of a target performance of a substrate processing system. For example, target performance may include target energy efficiency, target throughput, target environmental impact, or the like.

At block 442, processing logic provides the first indication to a process modeling platform. The process modeling platform may include a first process model and a second process model. The first process model and the second process model may be associated with a first and second substrate processing operation. The first process model and second process model may be associated with a deposition, etch, doping, annealing, lithography, or nitridation operation, or other types of substrate processing operations. The first process model and second process model may be associated with different types of substrate processing operations. The first process model and second process model may be trained machine learning models, physics-based models, digital twin models of process chambers, or the like.

At block 444, processing logic receives as output from the process modeling platform a set of process inputs associated with the target feature. The process inputs may be recipe operations, manufacturing parameters, process parameters, hardware parameters, or the like predicted to result in a substrate including the target feature. The process inputs may be inputs predicted to result in a processed substrate meeting one or more target performance thresholds. The process inputs may be inputs predicted to result in a processed substrate satisfying one or more target threshold performance conditions.

At block 446, processing logic performs a corrective action in view of the set of process inputs. The corrective action may include updating a process recipe. The corrective action may include updating one or more parameters of a substrate processing system.

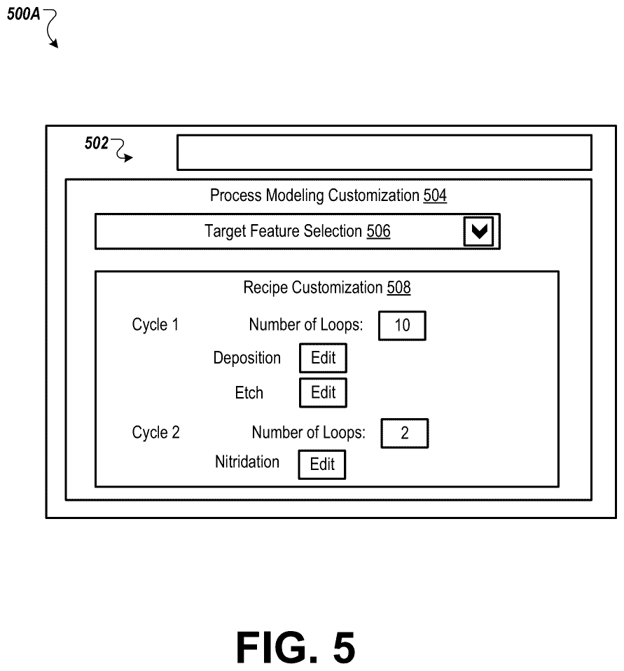

FIG. 5 is a view of a GUI 500A for user interaction with a process modeling platform, according to some embodiments. GUI 500A may be utilized in substrate design, recipe design, recipe improvement, or the like. GUI 500A includes a recipe selection 502. Recipe selection may include selection of a target substrate design, target device function, target sequence of process operations, target category of semiconductor device, or the like.

GUI 500A includes process modeling customization 504. Process modeling customization 504 may include user interface elements for selecting one or more characteristics of a modeling procedure. Process modeling customization 504 may include one or more elements for simulating a substrate manufacturing procedure. Process modeling customization 504 may include one or more elements for selecting simulation parameters. Process modeling customization 504 may include one or more elements for directing process simulation related to process inputs such as manufacturing parameters, manufacturing recipe parameters, or the like. Process modeling customization 504 may include one or more elements for directing a number of process models for predicting results of a series of processing operations performed on a substrate.

GUI 500A may further include target feature selection 506. Target feature selection 506 may include one or more user-interactable elements. Target feature selection 506 may enable selection of one or more features of interest. Target feature selection 506 may display indications of the one or more features of interest. Target feature selection 506 may be associated with one or more outputs of a process modeling platform. Target feature selection 506 may be used by the process modeling platform to select models to execute, e.g., models directed toward predicting characteristics of target features.

GUI 500A may further include recipe customization 508. Recipe customization 508 may enable user selection and/or alteration of process parameters, e.g., to predict effects of performing different process operations on a substrate. An appearance or recipe customization 508, including UI elements, information presented, number of elements, available customizations, etc., may be based on recipe selection 502, target feature selection 506, etc. Recipe customization 508 shown in FIG. 3 includes a number of example elements, but appearance of a recipe customization 508 may differ from that shown in FIG. 3.

Recipe customization 508 may include one or more UI elements for adjusting process modeling of a substrate processing procedure including multiple process operations, multiple types of operations, or the like. Recipe customization 508 may include one or more UI elements related to one or more cyclic processes. Recipe customization 508 may include UI elements related to different types of process operations, e.g., deposition, etch, and nitridation operations, as shown. Recipe customization 508 may include elements for adjusting operation of one or more cycles, one or more operations (which may or may not be included in cycles), or the like.

Recipe customization 508 may provide UI elements for updating various processing conditions associated with a target process operation. For example, a UI element may provide access to an editing UI element, where various aspects of a substrate process operation may be adjusted for modeling by a process modeling platform. For example, gas flows, pressures, temperatures, radio frequency (RF) characteristics, timings, chucking parameters, or the like, may be adjusted for process modeling. In some embodiments, recipe customization 508 may include selection of a target process chamber (e.g., and an associated model), selection of a generic (e.g., chamber-agnostic) model, selection of a target process chamber type, tool type, facility, or the like.

In some embodiments, a GUI may provide alternate data selection or entry options to a user. For example, a comprehensive modeling platform may be configure to provide predicted process settings corresponding to producing a product exhibiting target properties (e.g., target metrology, target features, target categorization, or the like). An associated GUI may provide UI elements enabling a user to, for example, input target substrate features, input chamber models, types, or IDs available for use, input process operations available, input acceptable ranges for process parameters, cycle counts, processing time, energy or material consumption, or the like, or other variables relevant to providing recommended process inputs for processing a substrate. The GUI may provide details of recommended process parameters for producing target products, the system may enact one or more changes to existing process recipes or create one or more new process recipes, enact the one or more adjusted or new process recipes (e.g., cause manufacturing equipment to process one or more substrates in accordance with the comprehensive modeling platform recommendations), or the like.

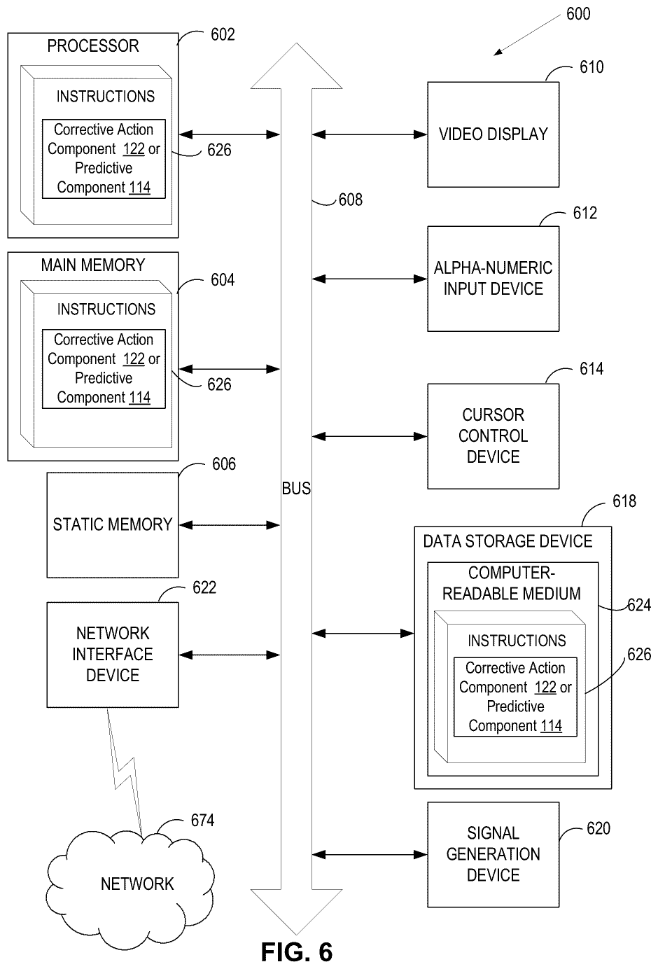

FIG. 6 is a block diagram illustrating a computer system 600, according to some embodiments. In some embodiments, computer system 600 may be connected (e.g., via a network, such as a Local Area Network (LAN), an intranet, an extranet, or the Internet) to other computer systems. Computer system 600 may operate in the capacity of a server or a client computer in a client-server environment, or as a peer computer in a peer-to-peer or distributed network environment. Computer system 600 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 600 may include a processing device 602, a volatile memory 604 (e.g., Random Access Memory (RAM)), a non-volatile memory 606 (e.g., Read-Only Memory (ROM) or Electrically-Erasable Programmable ROM (EEPROM)), and a data storage device 618, which may communicate with each other via a bus 608.

Processing device 602 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 600 may further include a network interface device 622 (e.g., coupled to network 674). Computer system 600 also may include a video display unit 610 (e.g., an LCD), an alphanumeric input device 612 (e.g., a keyboard), a cursor control device 614 (e.g., a mouse), and a signal generation device 620.

In some embodiments, data storage device 618 may include a non-transitory computer-readable storage medium 624 (e.g., non-transitory machine-readable medium, non-transitory machine-readable storage medium, or the like) on which may store instructions 626 encoding any one or more of the methods or functions described herein, including instructions encoding components of FIG. 1 (e.g., predictive component 114, corrective action component 122, model 190, etc.) and for implementing methods described herein. The non-transitory machine-readable storage medium may store instructions which are used to execute methods related to modeling one or more process operations of a process chamber, adjusting processing system operations to improve substrate processing operations, reducing defect formation of substrate processing, optimizing process conditions to produce substrates exhibiting target properties, or the like.

Instructions 626 may also reside, completely or partially, within volatile memory 604 and/or within processing device 602 during execution thereof by computer system 600, hence, volatile memory 604 and processing device 602 may also constitute machine-readable storage media.

While computer-readable storage medium 624 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “reducing,” “generating,” “correcting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

What is claimed is:

1. A method comprising:
obtaining, by a processing device, input data indicative of a first set of process parameters;
providing the input data to a first process model;
obtaining, from the first process model, first predictive output indicative of performance of a first process operation in accordance with the first set of process parameters;
providing the first predictive output to a second process model;
obtaining, from the second process model, second predictive output indicative of performance of a second process operation, different than the first process operation or a repetition of the first process operation, in accordance with the first set of process parameters; and
performing a corrective action in view of the second predictive output.

2. The method of claim 1, wherein the input data further comprises one or more indications of a substrate, the first predictive output further indicates a predicted result of performance of the first process operation on the substrate, and the second predictive output further indicates a predicted result of performance of the second process operation on the substrate.

3. The method of claim 1, wherein the first process operation comprises a first one of a:
deposition operation;
etch operation;
doping operation;
annealing operation;
lithography operation; or
nitridation operation.

4. The method of claim 3, wherein the second process operation comprises a second one of a deposition operation, etch operation, doping operation, annealing operation; lithography operation, or nitridation operation, different than the first.

5. The method of claim 1, wherein the first process model is associated with a first process chamber, and wherein the second process model is associated with a second process chamber.

6. The method of claim 1, wherein the corrective action comprises one of:
updating a process recipe;
scheduling maintenance;
updating the first process model; or
providing an alert to a user.

7. A method comprising:
obtaining, by a processing device, first data indicative of performance of a first process operation by a substrate processing system;
providing the first data to a first process model associated with a second process operation of the substrate processing system, different than the first process operation;
obtaining output of the first process model comprising predictive results of performance of the second process operation; and
performing a corrective action in view of the output of the first process model.

8. The method of claim 7, wherein the corrective action comprises one or more of:
updating one or more parameters of the substrate processing system;
updating one or more parameters of a substrate processing recipe associated with the second process operation; or
providing an alert to a user.

9. The method of claim 7, wherein the first data comprises a metrology measurement of a first feature of a substrate subsequent to performance of the first process operation.

10. The method of claim 7, wherein the first data comprises sensor data of the substrate processing system.

11. The method of claim 7, wherein the first process model comprises a trained machine learning model or a physics-based model.

12. The method of claim 7, wherein the first process model comprises a digital twin model of a first process chamber of the substrate processing system.

13. The method of claim 7, wherein the first process operation comprises one of a deposition operation, an etch operation, a doping operation, an annealing operation, a lithography operation, or a nitridation operation, and wherein the second process operation comprise a second one of these operations, different than the first.

14. The method of claim 7, wherein the substrate processing system comprises a semiconductor wafer manufacturing system.

15. A method comprising:
obtaining, by a processing device, a first indication of a target feature of a substrate;
providing the first indication to a process modeling platform, wherein the process modeling platform comprises a first process model and a second process model;
receiving as output from the process modeling platform a set of process inputs associated with the target feature; and
performing a corrective action in view of the set of process inputs.

16. The method of claim 15, wherein the corrective action comprises updating a process recipe or updating one or more parameters of a substrate processing system.

17. The method of claim 15, wherein the first process model is associated with a first process operation, and wherein the second process model is associated with a second process operation.

18. The method of claim 17, wherein the first process operation is a first of either a:
deposition operation;
etch operation;
doping operation;
annealing operation;
lithography operation; or
nitridation operation, and wherein the second process operation is a second of these operations, different than the first.

19. The method of claim 15, wherein the first process model comprises a trained machine learning model or a physics-based model.

20. The method of claim 15, wherein the first process model is associated with a first process chamber, and wherein the second process model is associated with a second process chamber.
